(19) United States
(12) Patent Application Publication
(10) Pub. No.: US 2026/0123469 A1
(43) Pub. Date: Apr. 30, 2026

(54) SEMICONDUCTOR PACKAGE

(71) Applicant: SAMSUNG ELECTRONICS CO., LTD., Suwon-si (KR)

(72) Inventors: KIJU LEE, Suwon-si (KR); JINSU KIM, Suwon-si (KR); IKKYU JIN, Suwon-si (KR)

(73) Assignee: SAMSUNG ELECTRONICS CO., LTD., Suwon-si (KR)

(21) Appl. No.: 19/259,451

(22) Filed: Jul. 3, 2025

(30) Foreign Application Priority Data
Oct. 24, 2024 (KR) 10-2024-0146643

(51) Int. Cl. H01L 23/538; H01L 25/065; H10B 80/00; H10D 80/30

(52) U.S. Cl. CPC H10W 70/611; H10W 70/685; H10W 90/00; H10B 80/00; H10D 80/30; H10W 90/724

(57) ABSTRACT

A semiconductor package may include: a substrate including wiring layers that are stacked; a connection pad on a lower surface of the substrate; a first protective layer on a lower surface of the connection pad, and including a first recess region on a lower surface of the first protective layer; a metal layer on the first recess region of the first protective layer; and a connection terminal on a lower surface of the metal layer. The wiring layers may include an insulating pattern and a wiring pattern, the wiring pattern may be electrically connected to the connection pad, and the lower surface of the first protective layer may be curved.

### CROSS-REFERENCE TO RELATED APPLICATIONS

This U.S. non-provisional patent application claims priority under 35 U.S.C. § 119 of Korean Patent Application No. 10-2024-0146643, filed on Oct. 24, 2024, the entire contents of which are hereby incorporated by reference.

### BACKGROUND

### 1. Field

The present disclosure herein relates to a semiconductor package.

### 2. Description of Related Art

With development of the electronics industry, demand for high-performance, high-speed, and miniaturization of an electronic component is increasing. In response to this trend, recent packaging technology is moving in a direction in which a plurality of semiconductor chips are mounted in one package.

In a recent electronic product market, demand of a portable device is dramatically increasing, and thus miniaturization and lightweight of the electronic components mounted thereon are continuously required. In order to realize the miniaturization and the lightweight of the electronic components, not only a technology that reduces an individual size of the mounted component, but also a semiconductor package technology that integrates many individual devices into a single package is required.

As a plurality of semiconductor chips included in a semiconductor package are highly integrated, cases in which a printed circuit board does not accommodate the integration are frequently occurring. In order to solve this, the semiconductor package connecting the plurality of semiconductor chips using an interposer is being developed.

### SUMMARY

The present disclosure provides a semiconductor package with improved mechanical characteristics, and a method for manufacturing the same.

The present disclosure also provides a semiconductor package with improved stability.

A technical goal of the disclosure is not limited to the goal mentioned above, and other technical goals that are not mentioned may be clearly understood from description below by those skilled in the art.

According to an aspect of the disclosure, a semiconductor package may include: a substrate including wiring layers that are stacked; a connection pad on a lower surface of the substrate; a first protective layer on a lower surface of the connection pad, and including a first recess region on a lower surface of the first protective layer; a metal layer on the first recess region of the first protective layer; and a connection terminal on a lower surface of the metal layer. The wiring layers may include an insulating pattern and a wiring pattern, the wiring pattern may be electrically connected to the connection pad, and the lower surface of the first protective layer may be curved.

According to an aspect of the disclosure, a semiconductor package may include: a substrate; a connection pad on a lower surface of the substrate; a metal layer on a lower surface of the connection pad; an inner protective layer between the connection pad and the metal layer, and around a side surface of the metal layer; an outer protective layer between the connection pad and the inner protective layer, and around a side surface of the inner protective layer; and a connection terminal on a lower surface of the metal layer. A lowermost end of the inner protective layer may be lower than a lowermost end of the outer protective layer.

According to an aspect of the disclosure, a semiconductor package may include: a substrate; a connection pad on a lower surface of the substrate; a metal layer on a lower surface of the connection pad; an inner protective layer around a side surface of the metal layer; an outer protective layer around a side surface of the inner protective layer; and a connection terminal on a lower surface of the metal layer. The inner protective layer may include copper (Cu), and the outer protective layer includes titanium (Ti).

### BRIEF DESCRIPTION OF THE DRAWINGS

The accompanying drawings are included to provide a further understanding of the disclosure, and are incorporated in and constitute a part of this specification. The drawings illustrate one or more embodiments of the disclosure and, together with the description, serve to explain principles of the disclosure. In the drawings:

FIG. 1 is a cross-sectional view illustrating a semiconductor package according to one or more embodiments of the disclosure;

FIG. 2 is an enlarged diagram for describing a portion of a semiconductor package according to one or more embodiments of the disclosure, and is an enlarged diagram of portion N of FIG. 1;

FIG. 3 is an enlarged diagram for describing a portion of a semiconductor package according to one or more embodiments of the disclosure, and is an enlarged diagram of portion N of FIG. 1;

FIG. 4 is an enlarged diagram for describing a portion of a semiconductor package according to one or more embodiments of the disclosure, and is an enlarged diagram of portion N of FIG. 1;

FIG. 5 is a plan view for describing a semiconductor package according to one or more embodiments of the disclosure;

FIG. 6 is a cross-sectional view for describing a semiconductor package according to one or more embodiments of the disclosure, and is a cross-sectional view taken along line A-A′ of FIG. 5;

FIG. 7 is a cross-sectional view for describing a method for manufacturing a semiconductor package according to one or more embodiments of the disclosure;

FIG. 8 is a cross-sectional view for describing a method for manufacturing a semiconductor package according to one or more embodiments of the disclosure;

FIG. 9 is a cross-sectional view for describing a method for manufacturing a semiconductor package according to one or more embodiments of the disclosure; and

FIG. 10 is a cross-sectional view for describing a method for manufacturing a semiconductor package according to one or more embodiments of the disclosure.

### DETAILED DESCRIPTION

Hereinafter, a semiconductor package according to the disclosure will be described with reference to the drawings.

In the specification, spatially relative terms such as “top”, “bottom”, “upper”, “lower”, “up”, “down”, “horizontal,” “vertical” etc. are used to easily explain the positional relationship of each component when viewed from a direction depicted in the drawings. Therefore, spatially relative terms indicating the positional relationship of each component may be understood differently when viewed from a direction other than the direction depicted in the drawings.

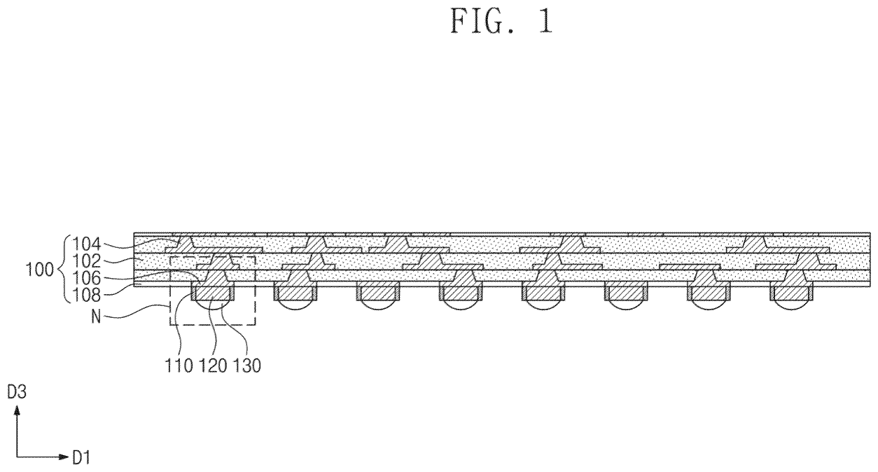

FIG. 1 is a cross-sectional view illustrating the semiconductor package according to one or more embodiments of the disclosure. FIG. 2 is a diagram for describing a portion of the semiconductor package according to one or more embodiments of the disclosure, and is an enlarged diagram of portion N of FIG. 1. Referring to FIGS. 1 and 2, an interposer substrate 100 may be provided. In the present specification, a first direction D1 may mean one direction parallel to an upper surface (or a lower surface) of the interposer substrate 100, and a third direction D3 may mean a direction vertical to the upper surface of the interposer substrate 100, and vertical to the first direction D1. The interposer substrate 100 may include at least one interposer wiring layer sequentially stacked. Each of the interposer wiring layers may include a substrate insulating pattern 102 and a substrate wiring pattern 104. The substrate wiring pattern 104 of any one interposer wiring layer may be electrically connected to the substrate wiring pattern 104 of another interposer wiring layer adjacent thereto. Hereinafter, the substrate insulating pattern 102 and the substrate wiring pattern 104 will be described with respect to the one interposer wiring layer.

The substrate insulating pattern 102 may include insulating polymer or photoimageable dielectric (PID). For example, the photoimageable dielectric may include at least one of photoimageable polyimide, polybenzoxazole (PBO), phenol-based polymer or benzocyclobutene-based polymer.

The substrate wiring pattern 104 may be provided on the substrate insulating pattern 102. The substrate wiring pattern 104 may be provided on a lower surface of the substrate insulating pattern 102. The substrate wiring pattern 104 may protrude onto the lower surface of the substrate insulating pattern 102. The substrate wiring pattern 104 may horizontally extend on the lower surface of the substrate insulating pattern 102. The substrate wiring pattern 104 on the lower surface of the substrate insulating pattern 102 may be covered by the substrate insulating pattern 102 of another interposer wiring layer disposed thereunder. Like the above, the substrate wiring pattern 104 may be a pad part or a wire part of the interposer wiring layer. That is, the substrate wiring pattern 104 may be a component for horizontal redistribution in the interposer substrate 100. The substrate wiring pattern 104 may include a conductive material. For example, the substrate wiring pattern 104 may include copper (Cu).

The substrate wiring pattern 104 may have a damascene structure. For example, the substrate wiring pattern 104 may have a via protruding onto an upper surface thereof. The via may be a component for vertically connecting the substrate wiring pattern 104 of the interposer wiring layers adjacent to each other. For example, the via may extend from the upper surface of the substrate wiring pattern 104, and may penetrate the substrate insulating pattern 102 to be connected to a lower surface of the substrate wiring pattern 104 of another interposer wiring layer located thereon. That is, a lower portion of the substrate wiring pattern 104 located under the substrate insulating pattern 102 may be a head part used as a horizontal wire or pad, and the via of the substrate wiring pattern 104 may be a tail part. The substrate wiring pattern 104 may have a shape of a T turned over.

FIG. 1 illustrates that the substrate wiring pattern 104 has the shape of the T turned over, but the disclosure is not limited thereto. For example, the via may protrude onto the lower surface of the substrate wiring pattern 104. For example, the via may extend from the lower surface of the substrate wiring pattern 104, and may penetrate the substrate insulating pattern 102 to be connected to an upper surface of the substrate wiring pattern 104 of another interposer wiring layer located thereunder. That is, an upper portion of the substrate wiring pattern 104 located on the substrate insulating pattern 102 may be a head part used as a horizontal wire or pad, and the via of the substrate wiring pattern 104 may be a tail part. That is, the substrate wiring pattern 104 may have a T shape.

A first substrate pad may be provided on the upper surface of the interposer substrate 100. In this case, the first substrate pad may be a portion of the substrate wiring pattern 104 exposed onto the upper surface of the interposer substrate 100, or may be a separate pad disposed on the substrate insulating pattern 102 of the interposer substrate 100 to be connected to the substrate wiring pattern 104. The first substrate pad may be provided in plurality. An upper substrate protective layer may be provided on the upper surface of the interposer substrate 100. The upper substrate protective layer may cover an uppermost interposer wiring layer. The upper substrate protective layer may cover an uppermost substrate insulating pattern 102, and may surround the first substrate pad. The first substrate pad may be exposed onto an upper surface of the upper substrate protective layer. The upper substrate protective layer may include an insulating polymer or photoimageable polymer. The upper substrate protective layer may not be provided as needed.

The second substrate pad 106 (connection pad) may be provided on a lower surface of the interposer substrate 100. The second substrate pad 106 may be a portion of the substrate wiring pattern 104 exposed onto the lower surface of the interposer substrate 100, or may be a separate pad disposed on the substrate insulating pattern 102 of the interposer substrate 100 to be connected to the substrate wiring pattern 104. The second substrate pad 106 may be provided in plurality.

A lower substrate protective layer 108 may be provided on the lower surface of the interposer substrate 100. The lower substrate protective layer 108 may cover a lowermost interposer wiring layer. The lower substrate protective layer 108 may cover a lowermost substrate insulating pattern 102, and may surround the second substrate pad 106. The second substrate pad 106 may be exposed onto a lower surface of the lower substrate protective layer 108. The lower substrate protective layer 108 may include insulating polymer or photoimageable polymer. The lower substrate protective layer 108 may not be provided as needed.

A protective layer 110 may be provided on the second substrate pad 106. The protective layer 110 may include a first protective layer 112 (outer protective layer) and a second protective layer 114 (inner protective layer). The first protective layer 112 may be provided on a lower surface of the second substrate pad 106. The first protective layer 112 may cover the lower surface of the second substrate pad 106. A first recess region RS1 may be provided on a lower surface of the first protective layer 112. The first recess region RS1 may face an inside of the first protective layer 112 from the lower surface of the first protective layer 112. Described differently, the first recess region RS1 may mean a region recessed from the lower surface of the first protective layer 112 in the third direction D3. The first recess region RS1 may be located on a central portion of the first protective layer 112. From a different view, a surrounding portion of the first protective layer 112 may protrude downward from a bottom surface of the first recess region RS1. Described differently, the first protective layer 112 may include a first part P1 covering the lower surface of the second substrate pad 106, and a second part P2 extending from the first part P1 in an opposite direction of the third direction D3. The second part P2 may mean the surrounding portion of the first protective layer 112. The second part P2 may surround a side surface of a second protective layer 114 to be described later. A width T1 from an inner side surface of the first recess region RS1 to an outer side surface of the first protective layer 112 may be about 0.1 μm to about 1 μm. The first recess region RS1 may have a planar shape of a circle, or a polygon. The lower surface of the first protective layer 112 may be a curved surface. The lower surface of the first protective layer 112 may have a concave shape. A level of the lower surface of the first protective layer 112 may not be constant along the first direction D1. For example, the level of the lower surface of the first protective layer 112 may become lower from the outer side surface of the first protective layer 112 to the inner side surface of the first recess region RS1. The first protective layer 112 may include a metal material. More specifically, the first protective layer 112 may include titanium (Ti) or stainless steel (SUS).

The second protective layer 114 may be provided on the first recess region RS1 of the first protective layer 112. The second protective layer 114 may be located on the bottom surface of the first recess region RS1. The second protective layer 114 may cover the bottom surface of the first recess region RS1, and the inner side surface of the first recess region RS1. The first protective layer 112 may surround an outer side surface of the second protective layer 114. A second recess region RS2 may be provided on a lower surface of the second protective layer 114. The second recess region RS2 may face an inside of the second protective layer 114 from the lower surface of the second protective layer 114. The second recess region RS2 may be located on a central portion of the second protective layer 114. On a different view, a surrounding portion of the second protective layer 114 may protrude downward from a bottom surface of the second recess region RS2. Described differently, the second protective layer 114 may include a third part P3 covering the bottom surface of the first recess region RS1 and a fourth part P4 extending from the third part P3 in an opposite direction of the third direction D3. The third part P3 may cover a lower surface of the first part P1 of the first protective layer 112. The fourth part P4 may mean the surrounding portion of the second protective layer 114. The fourth part P4 may be interposed between an inner side surface of the second part P2 and a side surface of a metal layer 120 to be described later. A width T2 from an inner side surface of the second recess region RS2 to the outer side surface of the second protective layer 114 may be about 0.1 μm to about 1 μm. An outer side surface of the second protective layer 114 may mean a side surface of the second protective layer 114 in contact with the inner side surface of the first recess region RS1 of the first protective layer 112. The second recess region RS2 may have a planar shape of a circle or a polygon. The lower surface of the second protective layer 114 may be a curved surface. The lower surface of the second protective layer 114 may have a concave shape. A level of the lower surface of the second protective layer 114 may not be constant along the first direction D1. For example, the level of the lower surface of the second protective layer 114 may become lower from the outer side surface of the second protective layer 114 to the inner side surface of the second recess region RS2. The curved surface of the first protective layer 112 may have a more gradual slope than the curved surface of the second protective layer 114, but the disclosure is not limited thereto. The second protective layer 114 may include a metal material. More specifically, the second protective layer 114 may include copper (Cu). A material that forms the second protective layer 114 may be different from a material that forms the first protective layer 112.

The metal layer 120 may be provided on a central portion of the lower surface of the second substrate pad 106. The metal layer 120 may be provided on the bottom surface of the second recess region RS2 of the second protective layer 114. The metal layer 120 may fill the second recess region RS2 of the second protective layer 114. The metal layer 120 may cover the bottom surface and the inner side surface of the second recess region RS2. A width in the first direction D1 of the metal layer 120 may be smaller than a width in the first direction D1 of the second substrate pad 106. The width of the metal layer 120 may be about 10 μm to about 80 μm, but the disclosure is not limited thereto. A height H1 in the third direction D3 of the metal layer 120 may be about 30 μm to about 50 μm. A level of a lower surface of the metal layer 120 may be the same as or lower than a level of a lowermost end of the second protective layer 114.

The metal layer 120 may include a conductive material. For example, the metal layer 120 may include copper (Cu). A material forming the metal layer 120 may be the same as a material forming the second protective layer 114, but the disclosure is not limited thereto.

An interposer connection terminal 130 may be provided on the lower surface of the metal layer 120. The interposer connection terminal 130 may include a solder ball. The interposer connection terminal 130 may not protrude onto the outer side surface of the first protective layer 112. In other words, the interposer connection terminal 130 may be narrower than the first protective layer 112 in the first direction D1. A width in the first direction D1 of the interposer connection terminal 130 may be the same as or smaller than the width in the first direction D1 of the second substrate pad 106. The interposer connection terminal 130 may include metal. For example, the interposer connection terminal 130 may include Sn, Ag, Cu, Bi or a mixture thereof, but the disclosure is not limited thereto. A material forming the interposer connection terminal 130 may not chemically react with a material forming the first protective layer 112.

Since the first protective layer 112 interposed between the second substrate pad 106 and the metal layer 120, and the second protective layer 114 interposed between the first protective layer 112 and the metal layer 120 and surrounding a side surface of the metal layer 120 are provided, the interposer connection terminal 130 may not flow onto the side surface of the protective layer 110. Accordingly, a height from the lower surface of the second substrate pad 106 to a lower surface of the interposer connection terminal 130 may be constant.

FIG. 2 illustrates that a level of the highest part of the lower surface of the second protective layer 114 is the same as a level of the lowermost end of the first protective layer 112, but the disclosure is not limited thereto. The lower surface of the first protective layer 112 and the lower surface of the second protective layer 114 may not be connected to each other. A lower surface of the protective layer 110 may have a stepped shape. For example, a level of the lowermost end of the first protective layer 112 may be higher than a level of the highest part of the lower surface of the second protective layer 114. The outer side surface of the second protective layer 114 may be at least partially exposed onto the first protective layer 112.

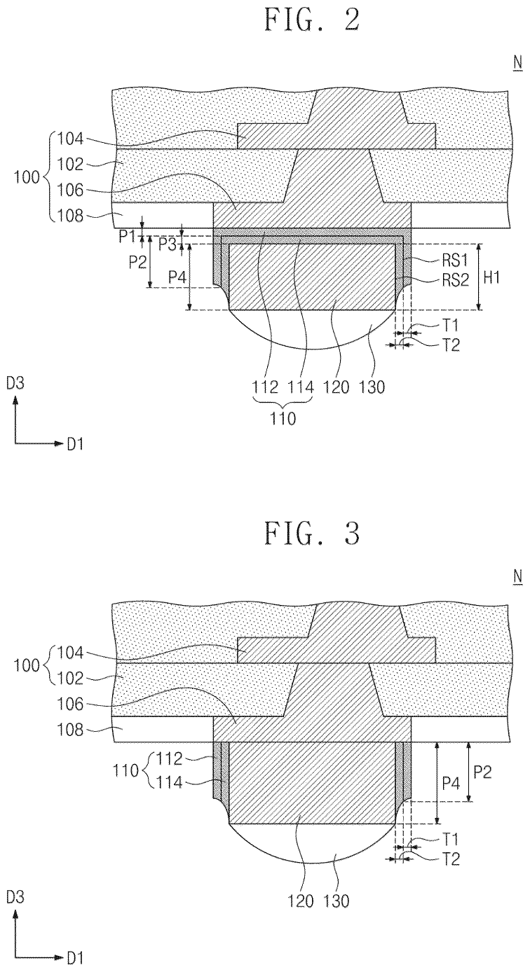

FIG. 3 is an enlarged diagram for describing a portion of the semiconductor package according to one or more embodiments of the disclosure, and is an enlarged diagram of part N of FIG. 1. Referring to FIG. 3, the protective layer 110 and the metal layer 120 may be provided on a lower surface of the second substrate pad 106 of the interposer substrate 100. The metal layer 120 and the second substrate pad 106 may be the same as or similar to what is described with reference to FIGS. 1 and 2. However, unlike FIG. 2, the upper surface of the metal layer 120 may be in contact with the lower surface of the second substrate pad 106. The second protective layer 114 may be provided on a side surface of the metal layer 120. The second protective layer 114 may include the fourth part P4 surrounding the side surface of the metal layer 120. The first protective layer 112 may be provided on a side surface of the second protective layer 114. The first protective layer 112 may include the second part P2 surrounding the side surface of the second protective layer 114. The first protective layer 112 may be the same as or similar to the first protective layer 112 (see FIG. 2) described with reference to FIG. 2 excluding the first part P1. The second protective layer 114 may be the same as or similar to the second protective layer 114 (see FIG. 2) described with reference to FIG. 2 excluding the third part P3. The width T1 from an outer side surface of the second protective layer 114 to an outer side surface of the first protective layer 112 may be about 0.1 μm to about 1 μm. The width T2 from a side surface of the metal layer 120 to an outer side surface of the second protective layer 114 may be about 0.1 μm to about 1 μm. A lower surface of the protective layer 110 may be a curved surface identically to what is described with reference to FIGS. 1 and 2, but the disclosure is not limited thereto, and the lower surface of the protective layer 110 may be a plane. For example, the lower surface of the protective layer 110 may be parallel to a lower surface of the metal layer 120. The interposer connection terminal 130 may be provided on the lower surface of the metal layer 120. The interposer connection terminal 130 may be the same as what is described with reference to FIGS. 1 and 2.

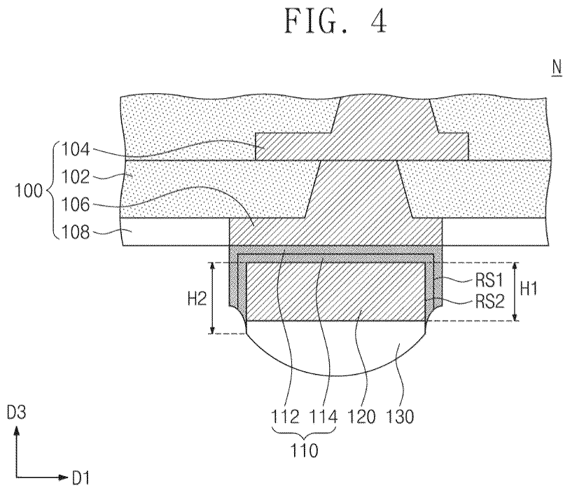

FIGS. 1 and 2 illustrate that a level of a lower surface of the metal layer 120 is the same as or lower than a level of a lowermost end of the second protective layer 114, but the disclosure is not limited thereto. FIG. 4 is an enlarged diagram for describing a portion of the semiconductor package according to one or more embodiments of the disclosure, and is an enlarged diagram of part N of FIG. 1.

Referring to FIG. 4, the protective layer 110 and the metal layer 120 may be provided on a lower surface of the second substrate pad 106. The second substrate pad 106 and the protective layer 110 may be the same as or similar to what is described with reference to FIGS. 1 and 2. However, unlike FIG. 2, a level of the lower surface of the metal layer 120 may be higher than a level of the lowermost end of the second protective layer 114. A distance from the lower surface of the second substrate pad 106 to the lower surface of the metal layer 120 may be shorter than a distance from the lower surface of the second substrate pad 106 to the lowermost end of the second protective layer 114. Described differently, the height H1 in the third direction D3 of the metal layer 120 may be smaller than the height H2 from a bottom surface of the second recess region RS2 to the lowermost end of the second protective layer 114.

The interposer connection terminal 130 may be provided on the lower surface of the metal layer 120. The interposer connection terminal 130 may be at least partially provided in the second recess region RS2. The second protective layer 114 may at least partially surround the interposer connection terminal 130.

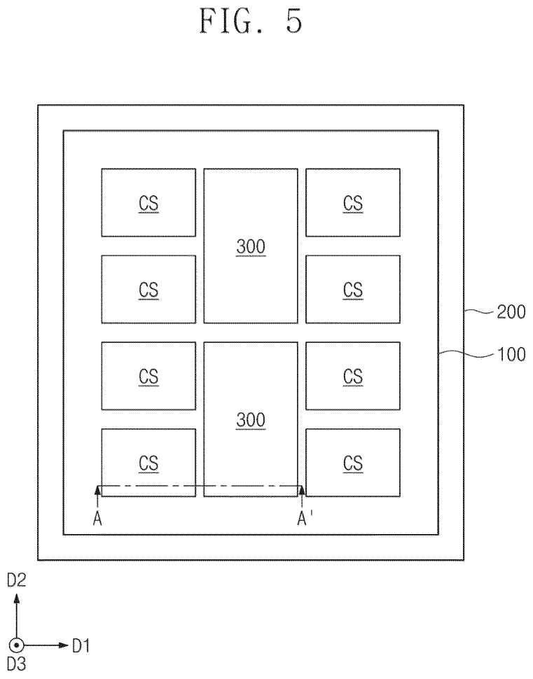

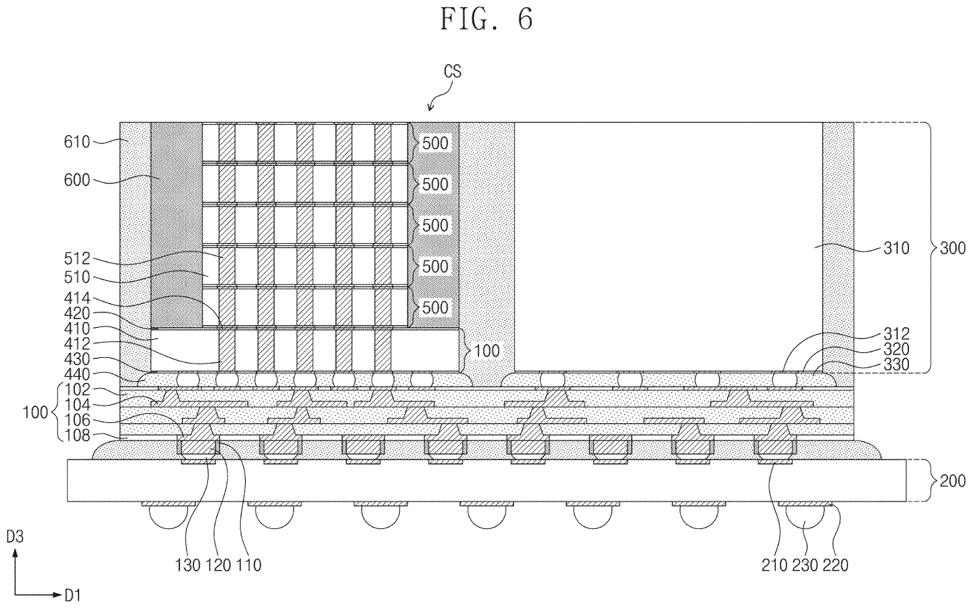

FIG. 5 is a plan view illustrating a semiconductor package according to one or more embodiments of the disclosure. FIG. 6 is a cross-sectional view illustrating the semiconductor package according to one or more embodiments of the disclosure, and is a cross-sectional view taken along line A-A′ of FIG. 5. Referring to FIGS. 5 and 6, the semiconductor package according to one or more embodiments of the disclosure may include a package substrate 200, an interposer substrate 100, chip stacks CS and a first semiconductor chip 300. The first semiconductor chip 300 may be provided on the package substrate 200 in plurality. The first semiconductor chips 300 may be spaced apart from each other on the package substrate 200 in a second direction D2. The second direction D2 may mean a direction parallel to an upper surface of the interposer substrate 100 and vertical to the first direction D1 and the third direction D3. The chip stack CS may be provided on the package substrate 200 in plurality. The chip stacks CS may be provided in the first direction D1 and an opposite direction of the first direction D1 of each of the first semiconductor chips 300. At least one of the chip stacks CS may be disposed in each of the first direction D1 and the opposite direction of the first direction D1 of the first semiconductor chips 300. Described differently, the chip stacks CS may be disposed in at least two columns extending in the second direction D2. The two columns of the chip stacks CS may be spaced apart from each other in the first direction D1. The first semiconductor chips 300 may be provided between the two columns of the chip stacks CS.

The package substrate 200 may be a redistribution substrate. For example, the package substrate 200 may include one substrate wiring layer or at least two substrate wiring layers mutually stacked. In the present specification, a substrate wiring layer may mean a wiring layer formed by patterning each of one insulating material layer and one conductive material layer. Each of the substrate wiring layers may include an insulating pattern and a conductive pattern in the insulating pattern. The conductive pattern of the any one substrate wiring layer may be electrically connected to the conductive pattern of the substrate wiring layer adjacent thereto.

The package substrate 200 may have an upper substrate pad 210. The upper substrate pad 210 may be an upper portion of the conductive pattern of the substrate wiring layer disposed on an uppermost end of the substrate wiring layers, or separate pads electrically connected to the conductive pattern in the substrate wiring layer. The upper substrate pad 210 may be disposed on an upper surface of the package substrate 200. The upper substrate pad 210 may be coplanar with the upper surface of the package substrate 200, and may be exposed onto the package substrate 200, but the disclosure is not limited thereto, and the upper substrate pad 210 may protrude onto the upper surface of the package substrate 200. The upper substrate pad 210 may be provided in plurality.

FIGS. 5 and 6 illustrate that the package substrate 200 is a redistribution substrate, but the disclosure is not limited thereto. According to other one or more embodiments, the package substrate 200 may be a printed circuit board (PCB). In this case, the package substrate 200 may have an internal wiring pattern provided in the package substrate 200. For example, the package substrate 200 may have a structure in which an insulating pattern and the internal wiring pattern are alternately stacked. In this case, the upper substrate pad 210 may be a separate pad electrically connected to the internal wiring pattern, or may be a portion of the internal wiring pattern protruding onto the upper surface of the package substrate 200. Hereinafter, one or more embodiments of FIGS. 5 and 6 will be continuously described.

A lower substrate pad 220 and a substrate connection terminal 230 may be provided on a lower surface of the package substrate 200. The lower substrate pad 220 may be a separate pad disposed on the lower surface of the package substrate 200 to be connected to the conductive pattern of the package substrate 200, or a portion of the conductive pattern exposed onto the lower surface of the package substrate 200, but the disclosure is not limited thereto, and the lower substrate pad 220 may protrude onto the lower surface of the package substrate 200. The substrate connection terminal 230 may include a solder ball, a solder bump, or the like. The lower substrate pad 220 and the substrate connection terminal 230 may be provided in plurality. Each of the substrate connection terminals 230 may be disposed on a lower surface of each of the corresponding lower substrate pads 220.

The interposer substrate 100 may be provided on the upper surface of the package substrate 200. In this case, the interposer substrate 100 may be the same as or similar to the interposer substrate 100 (see FIG. 1) described with reference to FIG. 1. The interposer substrate 100 may include a protective layer 110, a metal layer 120 and an interposer connection terminal 130 provided on a lower surface of the interposer substrate 100. The interposer substrate 100 may be mounted on the package substrate 200 through the interposer connection terminal 130. One end of the interposer connection terminal 130 may be in contact with the metal layer 120. The interposer connection terminal 130 may be electrically connected to the second substrate pad 106 through the metal layer 120. The other end of the interposer connection terminal 130 may be in contact with the upper substrate pad 210 of the package substrate 200.

The first semiconductor chips 300 and the chip stacks CS may be disposed on the interposer substrate 100. Hereinafter, for convenience of description, configuration of the first semiconductor chips 300 will be described with respect to one first semiconductor chip 300, and configuration of the chip stacks CS will be described with respect to one chip stack CS.

The first semiconductor chip 300 may be provided on the interposer substrate 100 in a face down form. A lower surface of the first semiconductor chip 300 may be an active surface. Hereinafter, in the present specification, a front surface may be defined as an active surface of an integrated device in a semiconductor chip, or one surface on which wires are formed, and a rear surface may be defined as an opposite surface opposed to the front surface. The first semiconductor chip 300 may include a first semiconductor substrate 310. The first semiconductor substrate 310 may include a semiconductor material. For example, the first semiconductor substrate 310 may include silicon (Si). An integrated device or integrated circuits may be provided on a lower surface of the first semiconductor substrate 310. The integrated device or the integrated circuits may include a logic circuit. That is, the first semiconductor chip 300 may be a logic chip.

A first chip pad 312 may be provided on the lower surface of the first semiconductor substrate 310. The first chip pad 312 may be coplanar with the lower surface of the first semiconductor substrate 310, and may protrude onto the lower surface of the first semiconductor chip 300, but the disclosure is not limited thereto. The first chip pad 312 may be coplanar with the lower surface of the first semiconductor substrate 310, and may be exposed onto the lower surface of the first semiconductor substrate 310. The first chip pad 312 may be electrically connected to the integrated device or the integrated circuits. The first chip pad 312 may include a conductive material. For example, the first chip pad 312 may include copper (Cu). A first insulating layer 320 may be provided on the lower surface of the first semiconductor substrate 310. The first insulating layer 320 may cover the lower surface of the first semiconductor substrate 310. The first insulating layer 320 may surround the first chip pad 312 on the first semiconductor substrate 310. The first chip pad 312 may be exposed onto a lower surface of the first insulating layer 320. The first insulating layer 320 may include silicon oxide (SiOx), silicon nitride (SiNx), or the like.

A chip connection terminal may be provided on a lower surface of the first chip pad 312. The chip connection terminal may include a solder ball or solder bump. One end of the chip connection terminal may be in contact with the first chip pads 312. The other end of the chip connection terminal may be in contact with the first substrate pad. The first chip pad 312 and the chip connection terminal may be provided in plurality. The first semiconductor chip 300 may be mounted on the interposer substrate 100 by the chip connection terminal.

A first underfill layer 330 may be provided between the lower surface of the first semiconductor chip 300 and the upper surface of the interposer substrate 100. The first underfill layer 330 may fill spaces between the interposer substrate 100 and the first semiconductor chip 300, and may surround the chip connection terminal.

The chip stack CS may be provided on the interposer substrate 100. The chip stack CS may be disposed, on the interposer substrate 100, horizontally spaced apart from the first semiconductor chip 300. The chip stack CS may include a base chip 400, second semiconductor chips 500 stacked on the base chip 400 and a first molding layer 600 surrounding the second semiconductor chips 500. Hereinafter, configuration of the chip stack CS will be described in detail.

The base chip 400 may include a base substrate 410. The base substrate 410 may be a semiconductor substrate. For example, the base substrate 410 may be a wafer-leveled semiconductor substrate made of semiconductor such as silicon (Si). A lower surface of the base chip 400 may be an active surface. A front surface of the base chip 400 may be disposed so as to face the upper surface of the package substrate 200. An integrated device or integrated circuits may be provided on a lower surface of the base substrate 410. For example, the integrated device or the integrated circuits may include a memory circuit. That is, the base chip 400 may be a memory chip such as a DRAM, an SRAM, an MRAM, or a flash memory. Alternatively, the integrated device or the integrated circuits may include a logic circuit. In this case, the base chip 400 may be a logic chip.

The base chip 400 may include a base penetration via 412. The base penetration via 412 may penetrate the base chip 400 in the third direction D3. One end of the base penetration via 412 may be in contact with an upper surface of the base substrate 410. The base penetration via 412 may be connected to the integrated device or the integrated circuits. The other end of the base penetration via 412 may be exposed onto the lower surface of the base substrate 410.

A base upper pad 414 may be provided on the upper surface of the base substrate 410. The base upper pad 414 may be connected to the base penetration via 412. The base penetration via 412 and the base upper pad 414 may be provided in plurality. Each of the base upper pads 414 may be in contact with an upper surface of each of the corresponding base penetration vias 412. A second insulating layer 420 may be provided on the upper surface of the base substrate 410. The second insulating layer 420 may cover the upper surface of the base substrate 410. The second insulating layer 420 may surround the base upper pad 414 on the base chip 400. The base upper pad 414 may be exposed onto an upper surface of the second insulating layer 420. The second insulating layer 420 may include silicon oxide (SiOx), silicon nitride (SiNx), or the like.

The base chip 400 may further include a base lower pad provided on the lower surface of the base substrate 410. The base lower pad may be coplanar with the lower surface of the base substrate 410, and may be exposed onto the lower surface of the base substrate 410. However, the disclosure is not limited thereto, and the base lower pad may protrude onto the lower surface of the base substrate 410. The base lower pad may be electrically connected to the integrated device or the integrated circuits through the base penetration via 412. A third insulating layer 430 covering the lower surface of the base substrate 410 may be provided. The third insulating layer 430 may surround the base lower pad on the lower surface of the base substrate 410. The base lower pad may be exposed onto a lower surface of the third insulating layer 430. The third insulating layer 430 may include silicon oxide (SiOx), silicon nitride (SiNx), or the like.

An external connection terminal such as a solder ball or solder bump may be provided on a lower surface of the base lower pad. The external connection terminal may include the solder ball or solder bump. One end of the external connection terminal may be in contact with the base lower pad. The external connection terminal may be electrically connected to the integrated device or the integrated circuits in the base chip 400. The external connection terminal and the base lower pad may be provided in plurality.

The second semiconductor chip 500 may be provided on the base chip 400. A width of the second semiconductor chip 500 may be smaller than a width of the base chip 400. A thickness of the second semiconductor chips 500 and the base chip 400 of the chip stack CS may be smaller than a thickness of the first semiconductor chip 300. The second semiconductor chip 500 may include a second semiconductor substrate 510 and a second chip penetration via 512.

The second semiconductor substrate 510 may be a semiconductor substrate. For example, the second semiconductor substrate 510 may include silicon (Si). A lower surface of the second semiconductor chip 500 may be an active surface. A front surface of the second semiconductor chip 500 may be disposed so as to face an upper surface of the base chip 400. An integrated device or integrated circuits may be provided on a lower surface of the second semiconductor substrate 510. For example, the integrated device or integrated circuits may include a memory circuit. That is, the second semiconductor chip 500 may be a memory chip such as a DRAM, an SRAM, an MRAM or a flash memory.

The second semiconductor chip 500 may include the second chip penetration via 512. The second chip penetration via 512 may penetrate the second semiconductor chips 500 in the third direction D3. One end of the second chip penetration via 512 may be in contact with an upper surface of the second semiconductor substrate 510. The second chip penetration via 512 may be connected to the integrated device or integrated circuits. The other end of the second chip penetration via 512 may be exposed onto the lower surface of the second semiconductor substrate 510.

The second semiconductor chip 500 may be provided in plurality. The second semiconductor chips 500 may be vertically stacked on the base chip 400. 4 to 32 of the second semiconductor chips 500 may be stacked, but the disclosure is not limited thereto. Side surfaces of the second semiconductor chips 500 may be vertically aligned with each other. The base chip 400 and the second semiconductor chips 500 may be electrically connected to each other. In this case, an uppermost second semiconductor chip 500 may not include the second chip penetration via 512 as needed. In addition, a thickness of the uppermost second semiconductor chip 500 may be greater than a thickness of other second semiconductor chips 500 disposed thereunder.

The second semiconductor chips 500 may be directly bonded. Each of the second semiconductor chips 500 may include a second chip lower pad provided on a lower surface of the second semiconductor chip 500 and a second chip upper pad provided on an upper surface of the second semiconductor chip 500. The second chip lower pad and the second chip upper pad may be each electrically connected to the second chip penetration via 512. On an interface of any two second semiconductor chips 500, the second chip lower pad of any one second semiconductor chip 500 and the second chip upper pad of the other second semiconductor chip 500 may be directly bonded to each other. For example, the second chip lower pad and the second chip upper pad may form an intermetallic hybrid bonding. The base chip 400 and the second semiconductor chip 500 of a lowermost end may be directly bonded to each other. On an interface of the base chip 400 and the second semiconductor chip 500 of the lowermost end, the second chip lower pad of the second semiconductor chip 500 and the base upper pad 414 of the base chip 400 of the lowermost end may be directly bonded to each other. For example, the second chip lower pad and the base upper pad 414 may form the intermetallic hybrid bonding.

The first molding layer 600 may be disposed on the upper surface of the base chip 400. The first molding layer 600 may cover the upper surface of the base chip 400. The first molding layer 600 may surround the second semiconductor chips 500. An upper surface of the first molding layer 600 may be coplanar with an upper surface of an uppermost second semiconductor chip 500. The uppermost second semiconductor chip 500 may be exposed onto the upper surface of the first molding layer 600. The first molding layer 600 may include an insulating polymer material. For example, the first molding layer 600 may include an epoxy molding compound (EMC).

The chip stack CS may be mounted on the interposer substrate 100. For example, the chip stack CS may be connected to the first substrate pad disposed on the upper surface of the interposer substrate 100 through the external connection terminal of the base chip 400. The external connection terminal may be in contact with an upper surface of the first substrate pad and the base lower pad to electrically connect the chip stack CS and the interposer substrate 100. A second underfill layer 440 may be provided between the interposer substrate 100 and the chip stack CS. The second underfill layer 440 may fill a space between the interposer substrate 100 and the base chip 400, and may surround the external connection terminal.

A second molding layer 610 may be provided on the interposer substrate 100. The second molding layer 610 may cover the upper surface of the interposer substrate 100, and may surround the chip stack CS and the first semiconductor chip 300. An upper surface of the second molding layer 610 may be coplanar with an upper surface of the chip stack CS and an upper surface of the first semiconductor chip 300. The second molding layer 610 may include an insulating polymer material. For example, the second molding layer 610 may include an epoxy molding compound (EMC).

FIG. 5 illustrates that the semiconductor package includes the first semiconductor chips 300 and the chip stacks CS, but the disclosure is not limited thereto. One first semiconductor chip 300 and one chip stack CS may be provided on the package substrate 200. In this case, the first semiconductor chips 300 and the chip stack CS may be spaced apart from each other on the package substrate 200. Alternatively, the first semiconductor chip 300 and a plurality of chip stacks CS may be provided. For example, the chip stacks CS may be spaced apart from each other in the second direction D2, and may be disposed on one side of the first semiconductor chip 300. Like the above, numbers and disposition of the first semiconductor chips 300 and the chip stacks CS may be changed as needed.

In addition, FIG. 6 illustrates that the second semiconductor chips 500 are directly bonded, but the disclosure is not limited thereto. Connection bumps may be provided on the lower surface of each of the second semiconductor chips 500. The connection bumps may electrically connect the base chip 400 and a lowermost second semiconductor chip 500. The connection bumps may be respectively provided between the second semiconductor chips 500 to electrically connect the second semiconductor chips 500. In this case, adhesive layers may be provided between the second semiconductor chips 500. The adhesive layers may surround the connection bumps between the second semiconductor chips 500, and may prevent an electrical short circuit between the connection bumps from occurring.

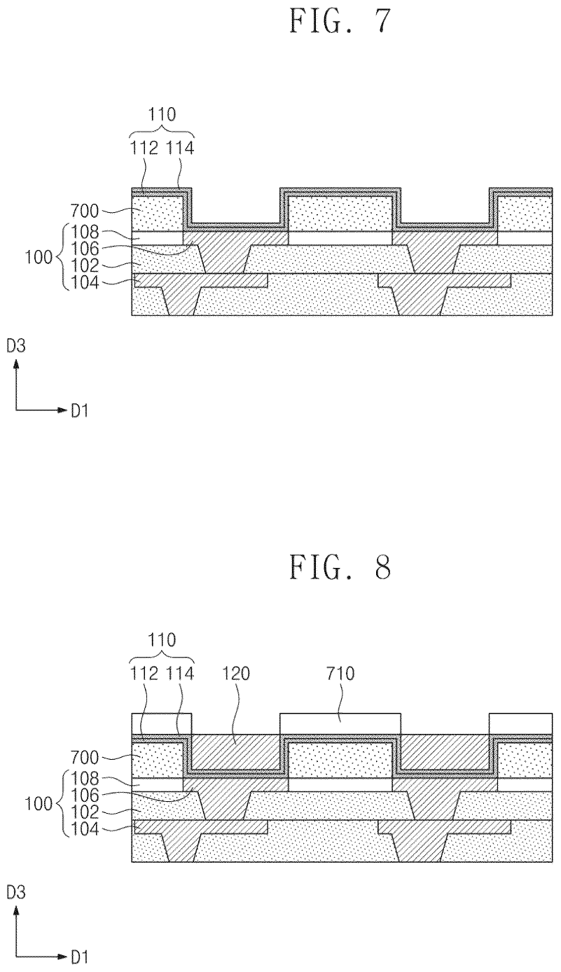

FIGS. 7 to 10 are cross-sectional views for describing a method for manufacturing a semiconductor package according to one or more embodiments of the disclosure. Some regions are enlarged in FIGS. 7 to 10 for convenience of description. Referring to FIG. 7, the interposer substrate 100 may be formed. For example, after an insulating layer is formed, one substrate insulating pattern 102 may be formed by patterning the insulating layer. After a conductive layer may be formed on the substrate insulating pattern 102, one substrate wiring pattern 104 may be formed by patterning the conductive layer. One interposer wiring layer may be formed through the above process. The interposer substrate 100 including a plurality of interposer wiring layers may be formed by repeatedly performing a process of forming the interposer wiring layer. In this case, an insulating layer formed on an uppermost end of the interposer wiring layer may be the lower substrate protective layer 108, and the substrate wiring pattern 104 penetrating the lower substrate protective layer 108 to be exposed onto the insulating layer of the uppermost end may be the second substrate pad 106. Alternatively, the second substrate pad 106 and the lower substrate protective layer 108 may be separately formed on an upper surface of the interposer wiring layer. Specifically, the lower substrate protective layer 108 may be formed by applying a photoimageable insulating layer on the uppermost interposer wiring layer. Penetration holes exposing the second substrate pad 106 may be formed by performing an exposure process and a develop process on the lower substrate protective layer 108. The second substrate pad 106 may be formed by filling the penetration holes of the lower substrate protective layer 108 with a conductive material. A plurality of interposer wiring layers, the lower substrate protective layer 108 and the second substrate pad 106 formed in the above method may constitute the interposer substrate 100 described with reference to FIGS. 1 and 2.

A first mask pattern 700 may be formed on the second substrate pad 106. The first mask pattern 700 may have openings exposing an upper surface of the second substrate pad 106. The first mask pattern 700 may include first openings located on the second substrate pad 106.

The protective layer 110 covering the first openings and the first mask pattern 700 may be formed. The protective layer 110 may cover an upper surface and a side surface of the first mask pattern 700, and the upper surface of the second substrate pad 106 exposed by the first openings. The protective layer 110 may include the first protective layer 112 and the second protective layer 114, and the first protective layer 112 and the second protective layer 114 may be substantially the same as or similar to what is described with reference to FIGS. 1 and 2. The first protective layer 112 may be applied onto the first mask pattern 700. The first protective layer 112 may cover the upper surface and the side surface of the first mask pattern 700, and the upper surface of the second substrate pad 106 exposed by the first openings. The second protective layer 114 may be applied onto the first protective layer 112. The second protective layer 114 may uniformly cover the first protective layer 112. Since the first mask pattern 700 has the first openings exposing the second substrate pad 106, the first protective layer 112 and the second protective layer 114 may have a form having a step. Described differently, the first protective layer 112 and the second protective layer 114 may have a region recessed in an opposite direction of the third direction D3, on the upper surface of the second substrate pad 106. The recessed region of the first protective layer 112 and the second protective layer 114 may respectively correspond to the first recess region RS1 (see FIG. 2) and the second recess region RS2 (see FIG. 2) described with reference to FIGS. 1 and 2.

Referring to FIG. 8, a second mask pattern 710 may be provided. The second mask pattern 710 may have second openings. For example, the second mask pattern 710 may include the second openings located on the second protective layer 114. The second openings may be located on a central portion of an upper surface of the second substrate pad 106. An upper surface of the second protective layer 114 may be partially exposed by the second openings. The second openings may expose the recessed region of the second protective layer 114. A plating process may be performed on the exposed region. The metal layer 120 may be formed in the plating process by filling the second openings with a metal material. The metal layer 120 may include a conductive material such as copper (Cu). The metal layer 120 may fill the recessed region of the second protective layer 114.

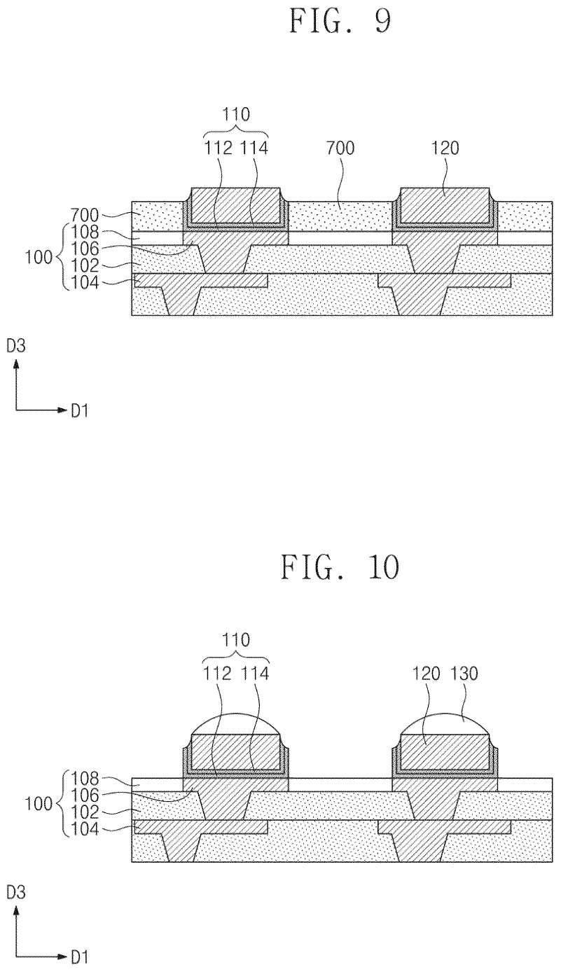

Referring to FIG. 9, the second mask pattern 710 may be removed. Thereafter, an etching process may be performed on the protective layer 110. The etching process may be a wet etching process using etchant. The protective layer 110 on the first mask pattern 700 may be at least partially etched and removed by the etching process. Specifically describing, one region of the protective layer 110 surrounding the metal layer 120 may be left, and the remaining region of the protective layer 110 covering an upper surface of the first mask pattern 700 may be etched. The etching process may be performed, and a curved surface may be formed in the first protective layer 112 and the second protective layer 114. A shape of the protective layer 110 formed by the etching process may be the same as what is described with reference to FIGS. 1 and 2. The etchant used in the etching process may chemically react with the first protective layer 112 more actively than with the second protective layer 114. The first protective layer 112 may be etched more than the second protective layer 114. Accordingly, the first protective layer 112 and the second protective layer 114 having a curved surface may be formed like what is described with reference to FIG. 2. The first protective layer 112 may have a lower uppermost level than the second protective layer 114.

Referring to FIG. 10, the first mask pattern 700 may be removed. The interposer connection terminal 130 may be provided on the metal layer 120. Thereafter, the metal layer 120 and the interposer connection terminal 130 may be adhered to each other by a reflow process. A result of FIG. 10 may be turned over. Like the above, the semiconductor package of FIG. 1 may be manufactured.

Since a semiconductor package according to one or more embodiments of the disclosure forms a protective layer surrounding a bump, a solder may be prevented from flowing onto a side surface of the bump. Accordingly, the semiconductor package with improved mechanical characteristics may be provided.

In addition, since the semiconductor package according to one or more embodiments of the disclosure forms the protective layer surrounding the bump so that the solder does not flow onto the side surface of the bump, a connection terminal having a constant height may be provided. Accordingly, the semiconductor package with improved stability may be provided.

Although the one or more embodiments of the present invention have been described, it is understood that the present invention should not be limited to these one or more embodiments but various changes and modifications can be made by one ordinary skilled in the art within the spirit and scope of the present invention as hereinafter claimed. Therefore, it should be understood that the one or more embodiments described above are exemplary in all respects and are not intended to be limiting.

What is claimed is:

1. A semiconductor package comprising:
a substrate comprising wiring layers that are stacked;
a connection pad on a lower surface of the substrate;
a first protective layer on a lower surface of the connection pad, and comprising a first recess region on a lower surface of the first protective layer;
a metal layer on the first recess region of the first protective layer; and
a connection terminal on a lower surface of the metal layer,
wherein the wiring layers comprise an insulating pattern and a wiring pattern,
wherein the wiring pattern is electrically connected to the connection pad, and
wherein the lower surface of the first protective layer is curved.

2. The semiconductor package of claim 1, further comprising:
a second protective layer around an inner side surface and a bottom surface of the first recess region, and between the first protective layer and the metal layer,
wherein the second protective layer comprises copper (Cu).

3. The semiconductor package of claim 2,
wherein the second protective layer comprises a second recess region on a lower surface of the second protective layer,
wherein the metal layer is in the second recess region, and
wherein the lower surface of the second protective layer is curved.

4. The semiconductor package of claim 2, wherein the first protective layer comprises any one of: titanium (Ti), stainless steel (SUS), or a combination thereof.

5. The semiconductor package of claim 2, wherein a width in a direction parallel to the lower surface of the substrate from a side surface of the metal layer to an outer side surface of the first protective layer is about 0.2 μm to about 2 μm.

6. The semiconductor package of claim 3,
wherein the lower surface of the metal layer is higher than a lowermost end of the second protective layer, and
wherein the connection terminal is at least partially in contact with an inner side surface of the second recess region.

7. The semiconductor package of claim 1, wherein the metal layer has a height of about 30 μm to about 50 μm.

8. The semiconductor package of claim 1, further comprising:
a plurality of the connection pad,
wherein a distance between two adjacent connection pads among the plurality of connection pads is about 20 μm to about 150 μm.

9. A semiconductor package comprising:
a substrate;
a connection pad on a lower surface of the substrate;
a metal layer on a lower surface of the connection pad;
an inner protective layer between the connection pad and the metal layer, and around a side surface of the metal layer;
an outer protective layer between the connection pad and the inner protective layer, and around a side surface of the inner protective layer; and
a connection terminal on a lower surface of the metal layer,
wherein a lowermost end of the inner protective layer is lower than a lowermost end of the outer protective layer.

10. The semiconductor package of claim 9, wherein the connection terminal is narrower than the outer protective layer in a direction parallel to the lower surface of the substrate.

11. The semiconductor package of claim 9,
wherein the outer protective layer comprises titanium (Ti), and
wherein the inner protective layer comprises copper (Cu).

12. The semiconductor package of claim 11, wherein the inner protective layer comprises a same material as the metal layer.

13. The semiconductor package of claim 9,
wherein the outer protective layer comprises a first part on the lower surface of the connection pad, and a second part extending from the first part around the side surface of the inner protective layer, and
wherein the inner protective layer comprises a third part on the first part of the outer protective layer, and a fourth part extending from the third part between an inner side surface of the second part and the side surface of the metal layer.

14. The semiconductor package of claim 13,
wherein a distance from the lower surface of the connection pad to the lower surface of the metal layer is shorter than a distance from the lower surface of the connection pad to the lowermost end of the inner protective layer, and
wherein the connection terminal is at least partially in contact with an inner side surface of the fourth part.

15. A semiconductor package comprising:
a substrate;
a connection pad on a lower surface of the substrate;
a metal layer on a lower surface of the connection pad;
an inner protective layer around a side surface of the metal layer;
an outer protective layer around a side surface of the inner protective layer; and
a connection terminal on a lower surface of the metal layer,
wherein the inner protective layer comprises copper (Cu), and the outer protective layer comprises titanium (Ti).

16. The semiconductor package of claim 15, wherein the metal layer has a height of about 30 μm to about 50 μm.

17. The semiconductor package of claim 15, further comprising:
a plurality of the connection pad,
wherein the plurality of connection pads are disposed, on the substrate, horizontally spaced apart from each other, and
wherein a distance between any two adjacent connection pads among the plurality of connection pads is about 20 μm to about 150 μm.

18. The semiconductor package of claim 15,
wherein the outer protective layer comprises a first part on the lower surface of the connection pad, and a second part extending from the first part around the side surface of the inner protective layer, and
wherein the inner protective layer comprises a third part on the first part of the outer protective layer, and a fourth part extending from the third part between an inner side surface of the second part and the side surface of the metal layer.

19. The semiconductor package of claim 15,
wherein a width in a direction parallel to the lower surface of the substrate from the side surface of the metal layer to an outer side surface of the inner protective layer is about 0.1 μm to about 1 μm, and
wherein a width in the direction parallel to the lower surface of the substrate from the outer side surface of the inner protective layer to an outer side surface of the outer protective layer is about 0.1 μm to about 1 μm.

20. The semiconductor package of claim 15, wherein a lowermost end of the inner protective layer is lower than a lowermost end of the outer protective layer.
